(19) United States
(12) Patent Application Publication
(10) Pub. No.: US 2014/0224751 A1
(43) Pub. Date: Aug. 14, 2014

(54) SOLAR PANEL MOUNTING STAND

(71) Applicant: SAWAKIGUMI CO., LTD., Oga-shi (JP)

(72) Inventor: Noriaki SAWAKI, Oga-shi (JP)

(21) Appl. No.: 14/178,609

(22) Filed: Feb. 12, 2014

(30) Foreign Application Priority Data
Feb. 12, 2013 (JP) 2013-024093

(51) Int. Cl. F24J 2/52; H01L 31/042

(52) U.S. Cl. CPC F24J 2/525; H01L 31/0422
USPC 211/41.1

(57) ABSTRACT

A solar panel mounting stand includes: a plurality of supporting legs installed at an installation site of the solar panel mounting stand, with six supporting legs in total as one set; three panel supporting racks, having an integral structure in which three members are combined to form a right triangle, and mounted on adjacent two supporting legs; a beam member configured to mutually connect members constituting an oblique side of the three panel supporting racks arranged in a row in the first direction; a brace member configured to connect members of the panel supporting rack in the center and the panel supporting rack at one end side; and a brace member configured to connect members of the panel supporting rack in the center and the panel supporting rack at the other end side, wherein the brace member and the brace member are disposed in a form a mountain shape.

### BACKGROUND

1. Field of the Invention

The present invention relates to a solar panel mounting stand for mounting solar power generation panels (hereinafter, referred to as “solar panels”) to generate electric power by means of sunlight.

2. Description of the Related Art

Recently, for the purpose of the prevention of global warming, solar-power plants represented by “mega solar” have been constructed. In such solar-power plants, a large number of solar panel mounting stands are generally installed on the ground (on the soil), and a plurality of solar panels are mounted to each solar panel mounting stand.

When taking into account the amount of electricity generated by solar energy and the impact of snowfall, it is preferred that solar panels be installed at a moderate inclined angle rather than installed horizontally. Therefore, many well-known solar panel mounting stands are designed such that solar panels are mounted at an inclined angle with regard to the horizontal plane perpendicular to the vertical plane (hereinafter, referred to as the “horizontal plane”) (e.g., refer to patent document 1).

Furthermore, a well-known solar panel mounting stand uses a concrete foundation as a base (e.g., refer to patent document 2). However, when using a concrete foundation as a base, the cost required for installing the solar panel mounting stand is high. Therefore, as a method without using a concrete foundation, the following method is known: a construct of a plurality of supporting legs are installed in the ground, and a solar panel mounting stand is constituted with those supporting legs as a base (foundation) (e.g., refer to patent document 3).

[Prior Art Document]

[Patent Document]

[Patent Document 1] Japanese Unexamined Patent Application Publication No. 2011-204953

[Patent Document 2] Japanese Unexamined Patent Application Publication No. 2012-87613

[Patent Document 3] Japanese Unexamined Patent Application Publication No. 2003-69062

In a solar panel mounting stand, to ensure rigidity required when solar panels are finally mounted to the solar panel mounting stand, a plurality of constituent members are used to form a solar panel mounting stand. In that case, to reduce cost required for installing the solar panel mounting stand, it is effective to reduce the number of constituent members required for assembling a solar panel mounting stand.

However, in a solar panel mounting stand designed such that solar panels are mounted at an inclined angle, specific members need to be disposed at an inclined angle in conformity with the inclined angle of the solar panel, and also many constituent members are required to ensure necessary rigidity. Specifically, in a solar panel mounting stand designed such that a plurality of supporting legs are installed in the ground instead of using a concrete foundation as a groundwork, those supporting legs must support the weight of the entire solar panel mounting stand. Therefore, many constituent members are required to suppress the entire rack from rocking; accordingly, the cost for installing a solar panel mounting stand tends to increase.

A main objective of the present invention is to provide the technology capable of reducing the cost for installing the solar panel mounting stand designed such that solar panels are mounted at an inclined angle to the horizontal plane.

### SUMMARY OF THE INVENTION

A first aspect of the present invention provides a solar panel mounting stand configured to mount a solar panel thereon in an inclination state inclined obliquely to a horizontal plane, including:

a plurality of supporting legs installed at an installation site, with six supporting legs in total as one set including three supporting legs arranged in a row in a first direction and two supporting legs arranged in a row in a second direction perpendicular to the first direction at the installation site of the solar panel mounting stand;

three panel supporting racks, having an integral structure in which three members are combined to form a right triangle, and mounted on adjacent two supporting legs in the second direction;

a beam member configured to mutually connect members constituting an oblique side of the three panel supporting racks arranged in a row in the first direction;

a first brace member configured to connect a member constituting a vertical side of the panel supporting rack mounted on a central supporting leg of three supporting legs adjacent to each other in the first direction, and a member constituting the vertical side of the panel supporting rack mounted on a supporting leg of the three supporting legs at one end side; and

a second brace member configured to connect a member constituting the vertical side of the panel supporting rack mounted on the central supporting leg of the three supporting legs adjacent to each other in the first direction, and a member constituting the vertical side of the panel supporting rack mounted on a supporting leg of the three supporting legs at the other end side;

wherein the first brace member and the second brace member are disposed in a form a mountain shape when said solar panel mounting stand is viewed from a front direction.

A second aspect of the present invention provides the solar panel mounting stand according to the first aspect, further including a third brace member configured to mutually connect two supporting legs adjacent to each other in the second direction and disposed in an inclination state inclined in the same direction as the direction of the member constituting the oblique side of the panel supporting rack.

A third aspect of the present invention provides the solar panel mounting stand according to the first aspect or the second aspect, wherein a projecting portion is provided on a lower end of the supporting leg, which is configured to inhibit a pull-off of the supporting leg under a load of the soil when a lower end side of the supporting leg is buried in the soil.

According to the present invention, in a solar panel mounting stand designed such that solar panels are mounted at an inclined angle to the horizontal plane, it is possible to ensure the necessary rigidity and also reduce the installation cost.

### BRIEF DESCRIPTION OF THE DRAWINGS

FIG. 1 shows a configuration example of a pile used as a solar panel mounting stand according to an embodiment of the present invention.

FIG. 2 is a cross-sectional view taken along the line A-A of FIG. 1.

FIG. 3 is a cross-sectional view taken along the line B-B of FIG. 1.

FIG. 4 is a front view showing a configuration example of a solar panel mounting stand according to an embodiment of the present invention.

FIG. 5 is a plan view showing a configuration example of a solar panel mounting stand according to an embodiment of the present invention.

FIG. 6 is a side view showing a configuration example of a solar panel mounting stand according to an embodiment of the present invention.

FIG. 7 is an enlarged view of a panel supporting rack (triangular rack).

FIG. 8 is a front view showing a configuration example of the structure for pile installation according to an embodiment of the present invention.

FIG. 9 is a plan view showing a configuration example of the structure for pile installation according to an embodiment of the present invention.

FIG. 10 is a side view showing a configuration example of the structure for pile installation according to an embodiment of the present invention.

FIG. 11 illustrates the configuration of the connecting fitting.

FIG. 12 is an explanatory diagram (part 1) for illustrating a method of installing a solar panel mounting stand according to an embodiment of the present invention.

FIG. 13 is an explanatory diagram (part 2) for illustrating the method of installing a solar panel mounting stand according to an embodiment of the present invention.

FIG. 14 is an explanatory diagram (part 3) for illustrating the method of installing a solar panel mounting stand according to an embodiment of the present invention.

FIG. 15 is an explanatory diagram (part 4) for illustrating the method of installing a solar panel mounting stand according to an embodiment of the present invention.

FIG. 16 is an explanatory diagram (part 5) for illustrating the method of installing a solar panel mounting stand according to an embodiment of the present invention.

FIG. 17 is an explanatory diagram (part 6) for illustrating the method of installing a solar panel mounting stand according to an embodiment of the present invention.

FIG. 18 is an explanatory diagram (part 7) for illustrating the method of installing a solar panel mounting stand according to an embodiment of the present invention.

FIG. 19 is an explanatory diagram (part 8) for illustrating the method of installing a solar panel mounting stand according to an embodiment of the present invention.

FIG. 20 is an explanatory diagram (part 9) for illustrating the method of installing a solar panel mounting stand according to an embodiment of the present invention.

FIG. 21 is an explanatory diagram (part 10) for illustrating the method of installing a solar panel mounting stand according to an embodiment of the present invention.

FIG. 22 is an explanatory diagram (part 11) for illustrating the method of installing a solar panel mounting stand according to an embodiment of the present invention.

FIG. 23 is an explanatory diagram (part 12) for illustrating the method of installing a solar panel mounting stand according to an embodiment of the present invention.

FIG. 24 is a front view showing solar panels mounted to a solar panel mounting stand.

FIG. 25 is a side view showing solar panels mounted to a solar panel mounting stand.

FIG. 26A, FIG. 26B, FIG. 26C and FIG. 26D show specific structural examples where respective members are fastened by bolts and nuts.

### DETAILED DESCRIPTION OF THE INVENTION

Hereinafter, embodiments of the present invention will be described in detail with reference to the drawings.

Embodiments of the present invention will be described according to the following sequential order:

1. Configuration of a pile according to an embodiment of the present invention

2. Configuration of a solar panel mounting stand according to an embodiment of the present invention

3. Configuration of a structure for pile installation according to an embodiment of the present invention

4. A method of installing a solar panel mounting stand according to an embodiment of the present invention

5. Advantageous effects of the embodiment of the present invention

6. Modified example, etc.

7. Other preferred embodiments of the present invention

<1. Configuration of a pile According to an Embodiment of the Present Invention>

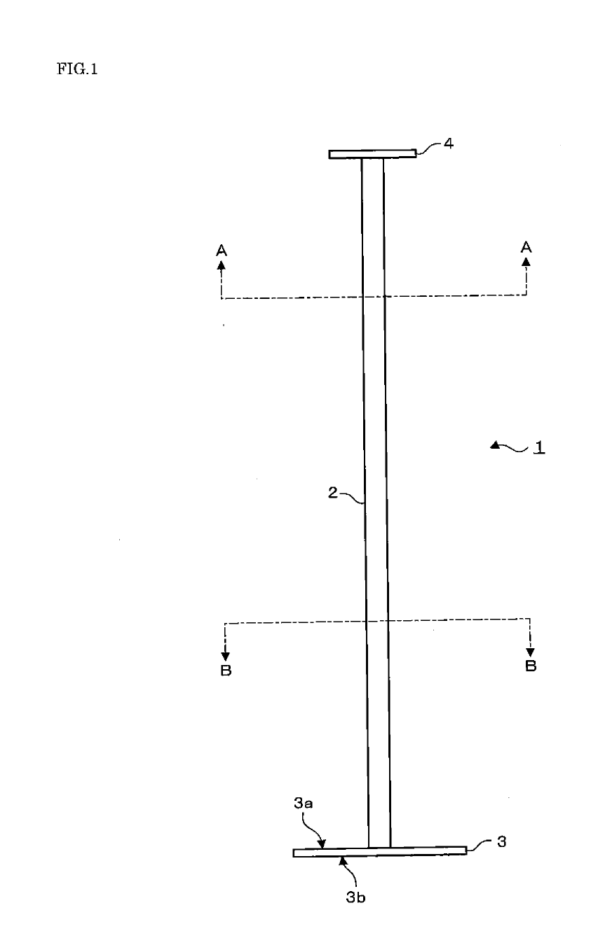

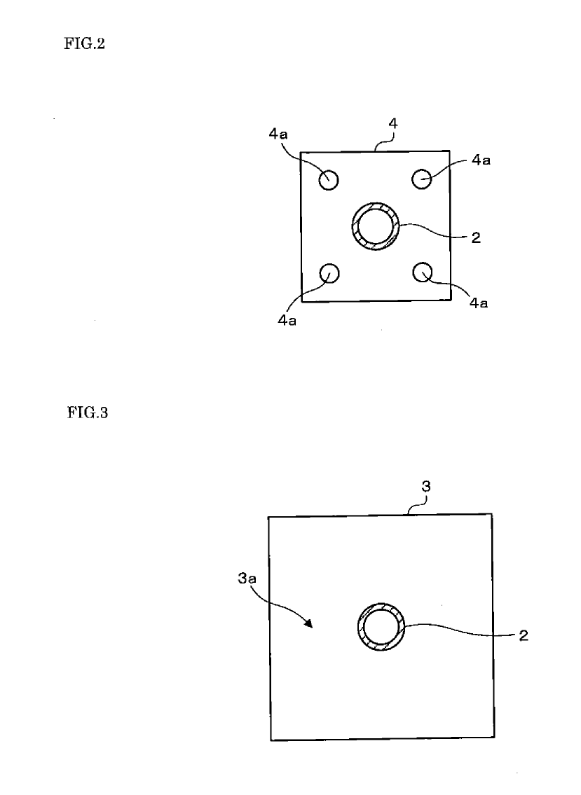

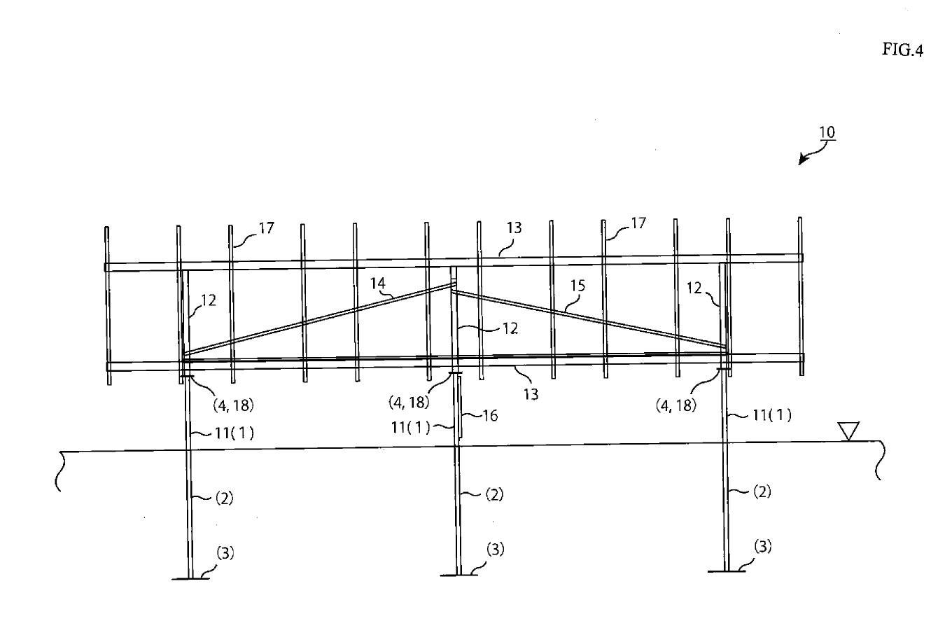

FIG. 1 shows a configuration example of a pile used as a supporting leg of a solar panel mounting stand according to an embodiment of the present invention. FIG. 2 is a cross-sectional view taken along the line A-A of FIG. 1, and FIG. 3 is a cross-sectional view taken along the line B-B of FIG. 1.

The pile 1, shown in the drawing, roughly comprises a pile body 2, a projecting portion 3, and a coupling portion 4.

The pile body 2 is entirely formed into a column. The cross section of the pile body 2 is circular. The pile body 2 can be formed, for example, by using a straight steel pipe (single pipe, etc.). The length of the pile body 2 is specified, for example, within a range between 2m and 4m by taking into account the length that is buried in the ground (in the soil) and the length that protrudes above the ground. The outer diameter of the pile body 2 is specified, for example, within a range of 40 mm or more and 60 mm or less by taking into account the load applied to the pile body 2.

The projecting portion 3 is provided at the lower end of the pile body 2 in the longitudinal direction of the pile body 2. The lower end of the pile body 2 is the end that is disposed downward when the pile 1 is installed in the ground. The projecting portion 3 is provided such that it projects in the radial direction of the pile body 2. The projecting portion 3 has the external size that is larger than the outer diameter of the pile body 2. The projecting portion 3 is formed into a non-spirally shape. In this embodiment, as an example of a non-spirally shape, the projecting portion 3 is formed into a flat plate.

By providing such a plate-like projecting portion 3 at the lower end of the pile body 2, it is indicated that the pile 1 is not intended to be driven or screwed into the ground for the installation. In this respect, this pile is completely different from other known piles. That is, normally, the lower end of the pile is formed into a thin conical shape to facilitate piling into the ground, or a spiral-shaped portion is provided at the tip of the pile to enable the pile to be screwed into the ground; however, in this embodiment, the lower end of the pile body 2 is equipped with a projecting portion 3 shaped such that it hinders the pile from being driven or screwed into the ground. The projecting portion 3 can be formed using a square steel plate, for example. The aforementioned pile body 2 is disposed at the central part of the projecting portion 3 when viewed from the direction of the central axis of the pile 1. The projecting portion 3 is, for example, fixed to the lower end of the pile body 2 by welding or a similar means. Of surfaces 3a and 3b of the projecting portion 3, one surface 3a is disposed upward and the other surface 3b is disposed downward when the pile 1 is installed. At the time of back-filling with soil, described later, one surface (hereinafter, also referred to as the “upper surface”) 3a of the projecting portion 3 is the surface that receives the load (weight pressure) of the soil, and the other surface (hereinafter, also referred to as the “lower surface”) 3b is the surface that comes in contact with (contacts) the ground at the scheduled installation site described later.

The coupling portion 4 is provided at the upper end of the pile body 2 in the longitudinal direction of the pile body 2. The upper end of the pile body 2 is the end that is disposed upward when the pile 1 is installed in the ground. The coupling portion 4 is provided so as to mount a member (described later), which serves as a framework of the solar panel mounting stand, to the pile 1. Similar to the aforementioned projecting portion 3, the coupling portion 4 is provided such that a square steel plate is fixed to the upper end of the pile body 2 by welding or a similar means. The coupling portion 4 is disposed so that it is opposite of the projecting portion 3 with the pile body 2 interposed. Furthermore, at both ends of the pile body 2, the coupling portion 4 and the projecting portion 3 are disposed parallel. Similar to the projecting portion 3, the coupling portion 4 is provided such that it projects in the radial direction of the pile body 2. The projecting portion 3 of the coupling portion 4 has four through-holes 4a. Each through-hole 4a is provided at each corner of the coupling portion 4. The external size of the coupling portion 4 is smaller than the external size of the projecting portion 3. As an example, when the projecting portion 3 and the coupling portion 4 are each made of a flat square plate, the external size of the coupling portion 4 is specified such that the length of one side is, for example, within a range of 150 mm or more and 200 mm or less, and the external size of the projecting portion 3 is specified such that the length of one side is, for example, within a range of 300 mm or more and 600 mm or less. Furthermore, the thickness of the projecting portion 3 and the coupling portion 4 (thickness of the plate) is each specified, for example, within a range of 4 mm or more and 8 mm or less. The surface of the pile 1 is rustproofed by means of molten zinc plating, etc.

<2. Configuration of a Solar Panel Mounting Stand According to an Embodiment of the Present Invention>

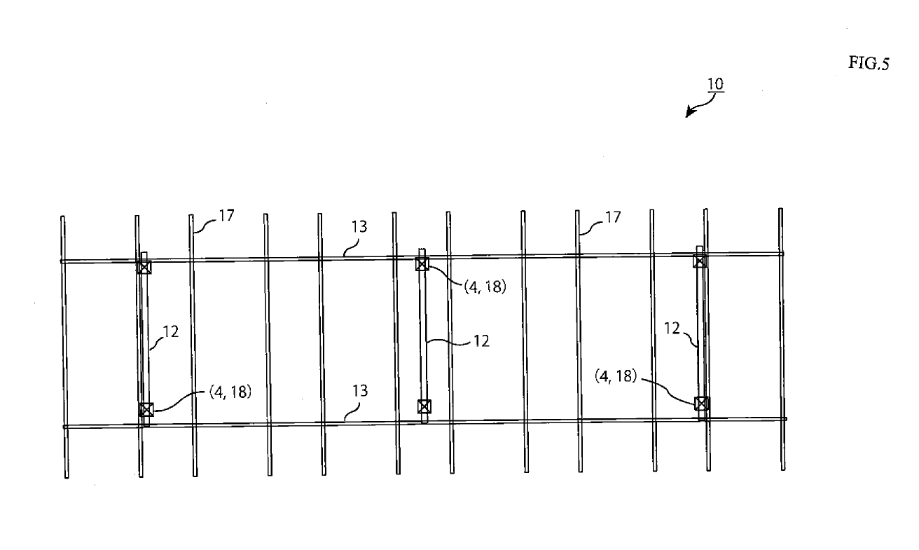

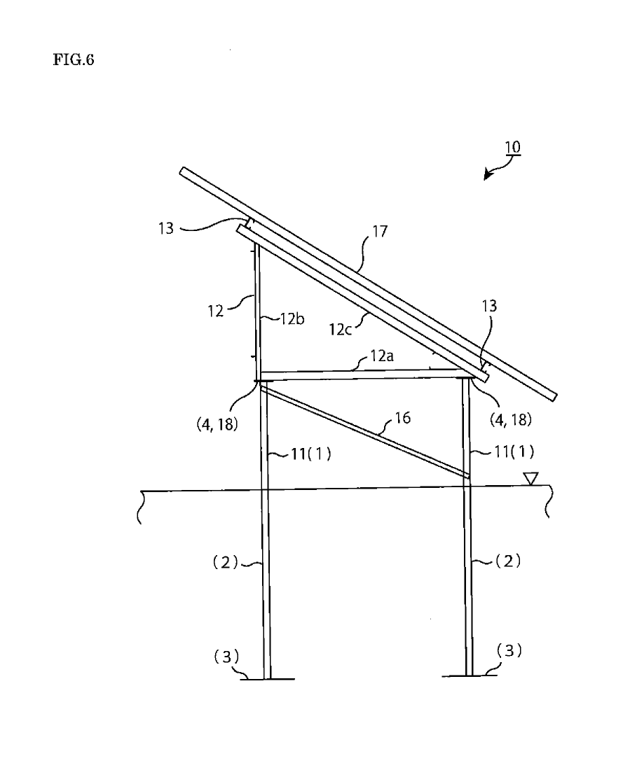

FIG. 4 is a front view showing a configuration example of a solar panel mounting stand according to an embodiment of the present invention, FIG. 5 is a plan view, and FIG. 6 is a side view of the same. Moreover, the inverted triangle mark in FIG. 4 and FIG. 6 indicates the assumed surface of the ground on which the solar panel mounting stand 10 is to be installed.

The solar panel mounting stand 10, shown in the drawing, roughly comprises a plurality of supporting legs 11 to serve as members that form the foundation of the mounting rack, and a plurality of panel supporting racks 12, a plurality of beam members 13, a plurality of brace members 14, 15, and 16, and a plurality of panel receiving members 17 to serve as members that form the framework of the mounting rack. Herein, one solar panel mounting stand 10 is made up of six supporting legs 11, three panel supporting racks 12, two beam members 13, three brace members 14, 15, and 16, and twelve panel receiving members 17. Among those, altogether six supporting legs 11, including three supporting legs 11 disposed in a row in the first direction at the installation site of the solar panel mounting stand and two supporting legs 11 disposed in a row in the second direction perpendicular to the first direction, are installed as a set at the above installation site. The “first direction” and the “second direction” described herein are the orthogonal biaxial directions parallel to the horizontal plane; and the “first direction” corresponds to the longitudinal direction of the solar panel mounting stand 10, and the “second direction” corresponds to the lateral direction of the solar panel mounting stand 10. The surface of each member is rustproofed (e.g., molten zinc plating for steel members).

Supporting legs 11 form the foundation of the solar panel mounting stand 10. The supporting leg 11 is made of the aforementioned pile 1. That is, the supporting leg 11 integrates the aforementioned pile body 2, projecting portion 3, and the coupling portion 4. When installing a solar panel mounting stand 10, the lower end of each supporting leg 11 is buried in the ground.

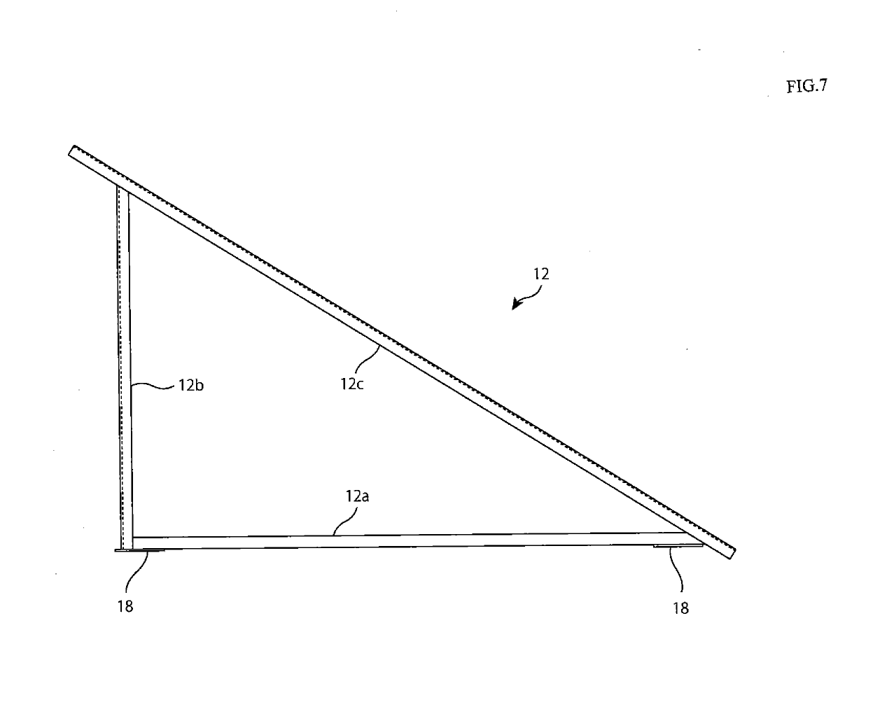

The panel supporting rack 12 is a triangular rack (triangle rack) to obliquely support solar panels. The panel supporting rack 12 is mounted onto the aforementioned supporting legs 11. When installing solar panels on the ground using a solar panel mounting stand 10, the solar panels are mounted to the solar panel mounting stand 10 in such a way that they are inclined at a predetermined angle (e.g., about 30 degrees) with regard to the horizontal plane. Therefore, the panel supporting rack 12 has an integral structure that combines three members to form a right triangle so as to include the oblique side that corresponds to the installation angle of the solar panel. The term “integral structure” described herein means the structure in which members are fastened together by welding or a similar means, instead of the structure in which members are fastened together by using bolts and nuts, for example. Whether a structure is an integral structure or not is determined by whether or not the structure can be disassembled without destroying the members. That is, the structure that is made up of members fastened together by using bolts and nuts can be disassembled by removing bolts and nuts. Therefore, this structure is not included in the integral structure. On the contrary, the structure that fastened members by welding or a similar means (including integral molding) cannot be disassembled without destroying the welded portions. Therefore, this structure is included in the integral structure. In this embodiment, as shown in FIG. 7, the three members are made of steel (e.g., channel steel) 12a, 12b, and 12c, and those steel members 12a, 12b, and 12c are fixed to one another by welding beforehand, thereby structurally integrating the panel supporting rack 12.

Of the three steel members 12a, 12b, and 12c, the steel member 12a forms the base of a right triangle, the steel member 12b forms the vertical side of the right triangle, and the steel member 12c forms the oblique side of the right triangle. The “base” described herein is the horizontally located side when the panel supporting rack 12 is mounted onto the aforementioned supporting legs 11, and the “vertical side” is the vertically (perpendicularly) located side when the panel supporting rack 12 is mounted onto the supporting legs 11. The “oblique side” is the “side opposite to the right angle”, as mathematically defined, which is obliquely located when the panel supporting rack 12 is mounted onto the supporting legs 11. The lower-level end of the steel member 12c protrudes such that it obliquely extends downward beyond the end of the steel member 12a. The upper-level end of the steel member 12c protrudes such that it obliquely extends upward beyond the upper end of the steel member 12b.

One end of the steel member 12a is equipped with a mounting plate 18, and the other end oppositely located is also equipped with another mounting plate 18. Respective mounting plates 18 are used to mount a panel supporting rack 12 onto two supporting legs 11 that are adjacent to each other in the lateral direction of the solar panel mounting stand 10. The two mounting plates 18 are disposed in the longitudinal direction of the steel member 12a at a predetermined distance (the same distance as the clearance between two piles 1 that are adjacent to each other in the lateral direction of the solar panel mounting stand 10). The mounting plate 18 is made of a flat steel plate that is shaped to fit the external size of the aforementioned coupling portion 4. When the mounting plate 18 and the coupling portion 4 are each made of a plate-like member of the same external size, positioning becomes easy when mounting the panel supporting rack 12 onto the piles 1. The mounting plate 18 has four through-holes that have the same positional relationships as the holes in the coupling portion 4. Therefore, when the mounting plate 18 is placed on top of the aforementioned coupling portion 4, the corresponding through-holes are disposed concentrically (ideal state). At one end of the steel member 12a, a mounting plate 18 is fixed to the lower surface of the steel member 12a by welding or a similar means. Also, at the other end of the steel member 12a, another mounting plate 18 is fixed to the lower surface of the steel member 12a and also to the lower end of the steel member 12b by welding or a similar means. Furthermore, the steel member 12b has through-holes (not shown) to mount brace members 14 and 15, and the steel member 12c has through-holes (not shown) to mount beam members 13.

The beam member 13 mutually connects steel members 12c constituting the oblique side of three panel supporting racks 12. Two beam members 13 are provided in total; one on the upper-level side and one on the lower-level side of the steel member 12c. Each beam member 13 can be formed, for example, using a long steel member (e.g., lip groove steel). Two beam members 13 are disposed in parallel to the longitudinal direction of the solar panel mounting stand 10. Furthermore, in the longitudinal direction of the solar panel mounting stand 10, both ends of each beam member 13 are disposed such that they protrude outward from each panel supporting rack 12 (lateral to the solar panel mounting stand 10). One beam member 13 is fixed to the upper-level end of the steel member 12c of the panel supporting rack 12 using bolts and nuts. The other beam member 13 is fixed to the lower-level end of the steel member 12c using bolts and nuts.

Brace members 14 and 15 are designed to mainly inhibit the solar panel mounting stand 10 from rocking in the longitudinal direction. The brace member 14 mutually connects the steel member 12b of the panel supporting rack 12 disposed at the center and the steel member 12b of the panel supporting rack 12 disposed at one-end side, among three panel supporting racks 12 disposed in the longitudinal direction of the solar panel mounting stand 10. Meanwhile, the brace member 15 mutually connects the steel member 12b of the above-mentioned panel supporting rack 12 disposed at the center and the steel member 12b of the panel supporting rack 12 disposed at the-other-end side. Those brace members 14 and 15 are disposed such that they form a mountain shape when the solar panel mounting stand 10 is viewed from the front. That is, the brace member 14 is obliquely disposed from the central panel supporting rack 12 to the one-end side panel supporting rack 12 so that it becomes gradually inclined; and the brace member 15 is obliquely disposed from the central panel supporting rack 12 to the the-other-end side panel supporting rack 12 so that it becomes gradually inclined. The brace members 14 and 15 can be each formed, for example, using a long steel member (e.g., L-shaped steel). One end and the other end of respective brace members 14 and 15 are fixed to the steel members 12b of the corresponding panel supporting racks 12 using bolts and nuts, for example.

Meanwhile, the brace member 16 is designed to mainly inhibit the solar panel mounting stand 10 from rocking in the lateral direction. The brace member 16 mutually connects two supporting legs 11 that support from below the central panel supporting rack 12. Furthermore, the brace member 16 is disposed such that it is inclined in the same direction as the steel member 12c of the panel supporting rack 12. Therefore, the brace member 16 is obliquely disposed so that it becomes gradually inclined from the back to the front when the solar panel mounting stand 10 is viewed from the front. The brace member 16 can be formed, for example, using the same steel (e.g., L-shaped steel) as the aforementioned brace members 14 and 15. One end and the other end of the brace member 16 are fixed to the corresponding supporting legs 11 using bolts and nuts, for example.

Panel receiving members 17 hold and support solar panels. A solar panel is equipped with a frame member made of aluminum, etc., for example, and the frame member can be mounted on the panel receiving members 17 using bolts and nuts, for example. The panel receiving member 17 can be formed using a long steel member (e.g., lip groove steel), for example.

A plurality of panel receiving members 17 are mounted in the longitudinal direction of the solar panel mounting stand 10 at appropriate intervals. The panel receiving members 17 are mounted such that they extend across two beam members 13. The panel receiving member 17 is inclined to the horizontal plane. The inclined angle of the panel receiving member 17 is the same as that of the steel member 12c of the panel supporting rack 12. One end of the panel receiving member 17 protrudes obliquely upward beyond the beam member 13 located below on the upper-level side. The other end of the panel receiving member 17 protrudes obliquely downward beyond the beam member 13 located below on the lower-level side. With the configuration in which both ends of the panel receiving member 17 thus protrude, it is possible to mount a larger number of solar panels to one solar panel mounting stand 10. Intervals among panel receiving members 17 that are adjacent to one another in the longitudinal direction of the solar panel mounting stand 10 are determined corresponding to the mounting holes provided in the frame member of the solar panels. Incidentally, solar panels are designed to be disposed (laid) in a reticular pattern using a plurality of panel receiving members 17.

<3. Configuration of a Structure for Pile Installation According to an Embodiment of the Present Invention>

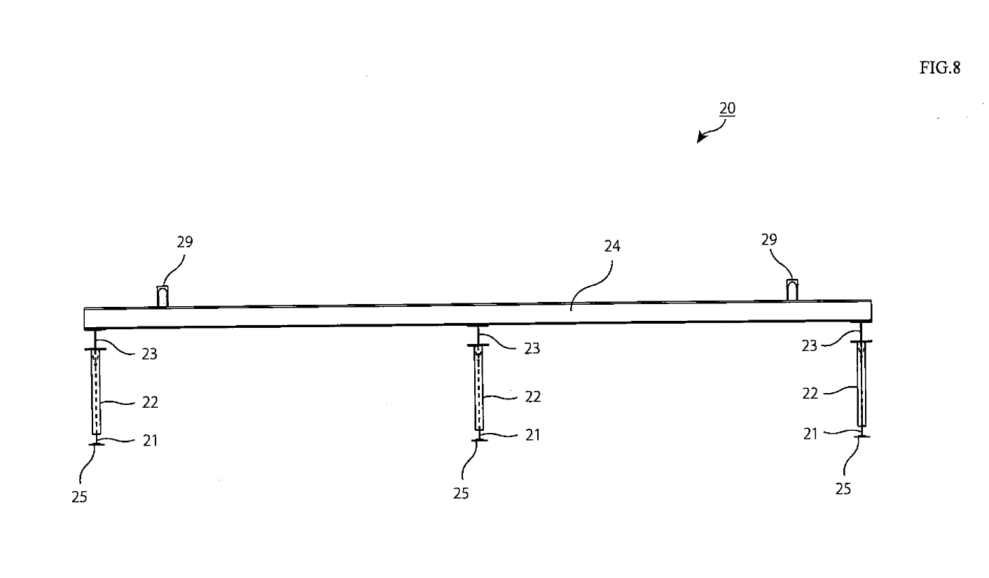

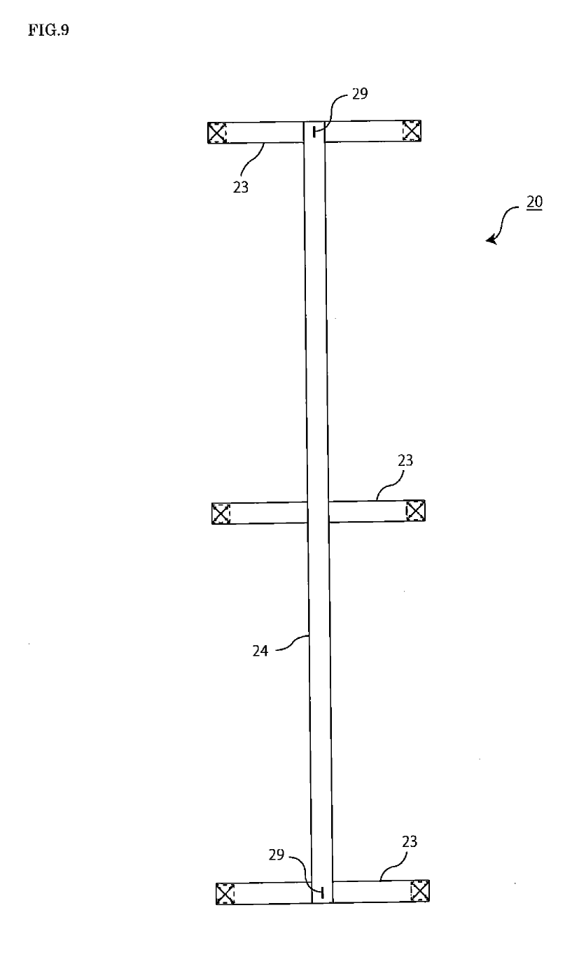

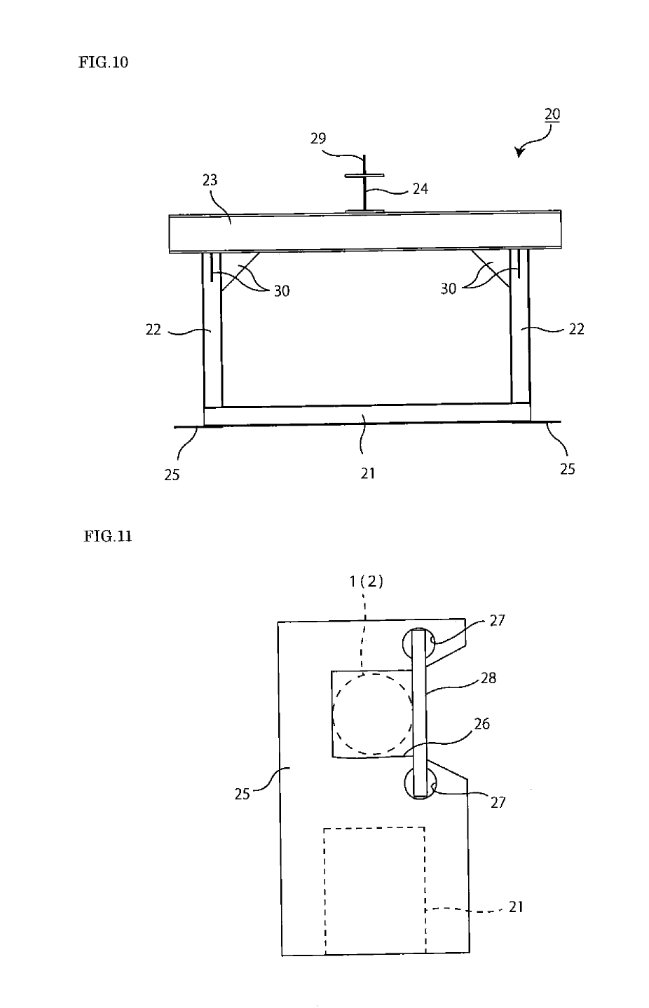

FIG. 8 is a front view showing a configuration example of the structure for pile installation according to an embodiment of the present invention, FIG. 9 is a plan view, and FIG. 10 is a side view of the same.

Upon installation of the solar panel mounting stand 10 on the ground, the structure 20, shown in the drawing, is designed to be used to install a plurality of piles 1 that serve as supporting legs 11 of the solar panel mounting stand 10. The structure 20 roughly comprises a plurality of lower-tier transverse beams 21, a plurality of supporting posts 22, a plurality of upper-tier transverse beams 23, and one vertical beam 24. Herein, as an example, one structure 20 comprises three lower-tier transverse beams 21, six supporting posts 22, three upper-tier transverse beams 23, and one vertical beam 24. However, the number, dimensions and arrangement of the members can be changed according to the number and arrangement of the piles 1 to be supported.

The lower-tier transverse beam 21 can be formed using I-shaped steel, for example. Plate-like connecting fittings 25 are provided respectively on both ends of the lower-tier transverse beam 21 in the longitudinal direction. When piles 1 are mounted on the structure 20, the connecting fittings 25 are detachably connected to the piles 1. Respective connecting fittings 25 are fixed to the lower surface of the lower-tier transverse beam 21 by welding or a similar means. A part of the connecting fitting 25 protrudes from the lower-tier transverse beam 21, and a notched portion 26, as shown in FIG. 11, is formed on the protruding portion. In FIG. 11, the portion within the broken line represented by number 21 indicates the welded portion that connects the connecting fitting 25 to the lower-tier transverse beam 21. The notched portion 26 allows the connecting fitting 25 to be mounted on and detached from a pile 1. Notched portions 26 of respective connecting fittings 25 are disposed in the same direction (one direction) in the longitudinal direction of the vertical beam 24. One side of the notched portion 26 (open side) is wide open so that it can easily direct the pile 1 to the back side of the notched portion 26.

Furthermore, the connecting fitting 25 has two through-holes 27. Those through-holes 27 are disposed with the notched portion 26 interposed. Each through-hole 27 is intended for mounting a brace 28 on the connecting fitting 25. For a brace 28, a clamp (metal bar member that is bent in a nearly horseshoe shape) can be used, for example. The brace 28 relatively fixes the pile 1 to the connecting fitting 25 by inserting both ends of the brace 28 into the two through-holes 27 while the pile 1 is engaged with the notched portion 26 of the connecting fitting 25.

The supporting post 22 can be formed using H-shaped steel, for example. The supporting post 22 vertically stands on the lower-tier transverse beam 21. The number of supporting posts 22 is the same as the number of piles 1 simultaneously supported by the structure 20. Both ends (upper and lower ends) of the supporting post 22 are fixed to the corresponding lower-tier transverse beam 21 and upper-tier transverse beam 23 by using bolts and nuts, for example.

The upper-tier transverse beam 23 is formed using H-shaped steel, for example. The upper-tier transverse beam 23 is disposed directly above the lower-tier transverse beam 21 parallel to the lower-tier transverse beam 21. The upper-tier transverse beam 23 has holes into which the coupling portions 4 of respective piles 1 are fitted. Furthermore, a reinforcing plate 30 is suitably mounted on each corner portion formed by the upper-tier transverse beam 23 and the supporting post 22 as needed.

The vertical beam 24 can be formed using H-shaped steel, for example. The vertical beam 24 is mounted so as to connect together three upper-tier transverse beams 23. The vertical beam 24 is mounted on respective upper-tier transverse beams 23 using bolts and nuts, for example, while the vertical beam 24 is placed on the upper surfaces of respective upper-tier transverse beams 23. Two metal hangers 29 are provided on the upper surface of the vertical beam 24. Those metal hangers 29 are disposed in the longitudinal direction of the vertical beam 24 at appropriate intervals.

Moreover, in FIG. 9, the intersection point indicated by the “X” provided at both ends of the upper-tier transverse beam 23 is the position where the central axis of the pile 1 is located when the pile 1 is mounted to the structure 20.

<4. A Method of Installing a Solar Panel Mounting Stand According to an Embodiment of the Present Invention>

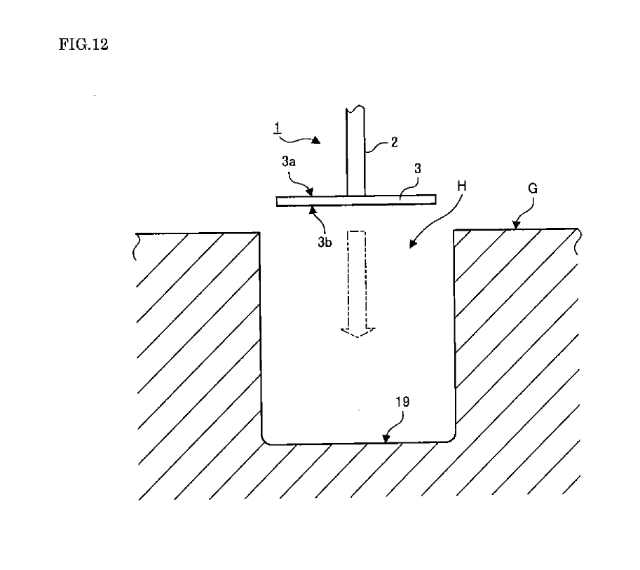

Next, a method of installing a solar panel mounting stand according to an embodiment of the present invention will be described with reference to FIG. 12 to FIG. 23.

First, upon installing the aforementioned solar panel mounting stand 10 on the ground, the soil (including sand) at the installation site is dug out. In this document, regardless of the size of particles constituting the soil, the term “soil” is used in a broad sense. When digging in the soil at the installation site of the solar panel mounting stand 10, the entire installation site may be dug out at a uniform depth. However, as the size of the solar panel mounting stand 10 increases, the area of the location at which the soil is dug out also increases accordingly. Therefore, it takes time and labor for the excavating work. For this reason, when digging out the soil at the installation site of the solar panel mounting stand 10, it is preferred that, over the entire installation site, only the soil at the exact locations at which a plurality of (six in this embodiment) piles 1 are scheduled to be installed should be removed. This construction method is adopted in this embodiment.

However, in that case, the side wall of hole H (see FIG. 12) tends to be collapsed during the excavating work depending on the type of the soil at the installation site. Therefore, it is desirable that the soil of the scheduled installation site of the pile 1 be dug out to a desired depth while preventing the hole H from collapsing by using square blocks. The excavation depth may be determined within a range between 1 m to 3 m, for example, although it depends on the weight and size of the solar panel mounting stand 10, weight of the solar panel, length of the pile 1, size of the projecting portion 3, etc.

By thus digging out the soil, at the installation site of the solar panel mounting stand 10, the planned installation ground surface 19 on which a pile 1 is scheduled to be installed can be formed at a depth deeper than the original ground G (ground surface before digging out) as shown in FIG. 12. The planned installation ground surface 19 is exposed at the bottom of the hole H after the soil has been dug out. The number of planned installation ground surfaces 19 is equal to the number of piles 1 to be installed and formed at the installation site of the solar panel mounting stand 10. Furthermore, it is desirable that leveling be conducted so that respective planned installation ground surfaces 19 can be at the same depth, with a common virtual horizontal plane as a reference.

Next, using the aforementioned structure 20, a plurality of (six in this embodiment) piles 1 are supported so that they are relatively positioned. The condition described herein as “relatively positioned” is the condition in which a plurality of piles 1 are positioned so that they have predetermined positional relationships (defined by design).

When supporting a plurality of piles 1 by the structure 20, respective piles 1 are mounted on the structure 20 as described below. Namely, while the pile body 2 of a pile 1 is engaged with the notched portion 26 of the connecting fitting 25, the coupling portion 4 of the pile 1 is fixed to a predetermined location of the upper-tier transverse beam 23 using bolts and nuts. Thereafter, the brace 28 is inserted from above into the through-hole 27 of the connecting fitting 25. Thus, a plurality of piles 1 are integrally supported by the structure 20. The term “integrally” described herein means that “so that the structure 20 and a plurality of piles 1 are immobilized”.

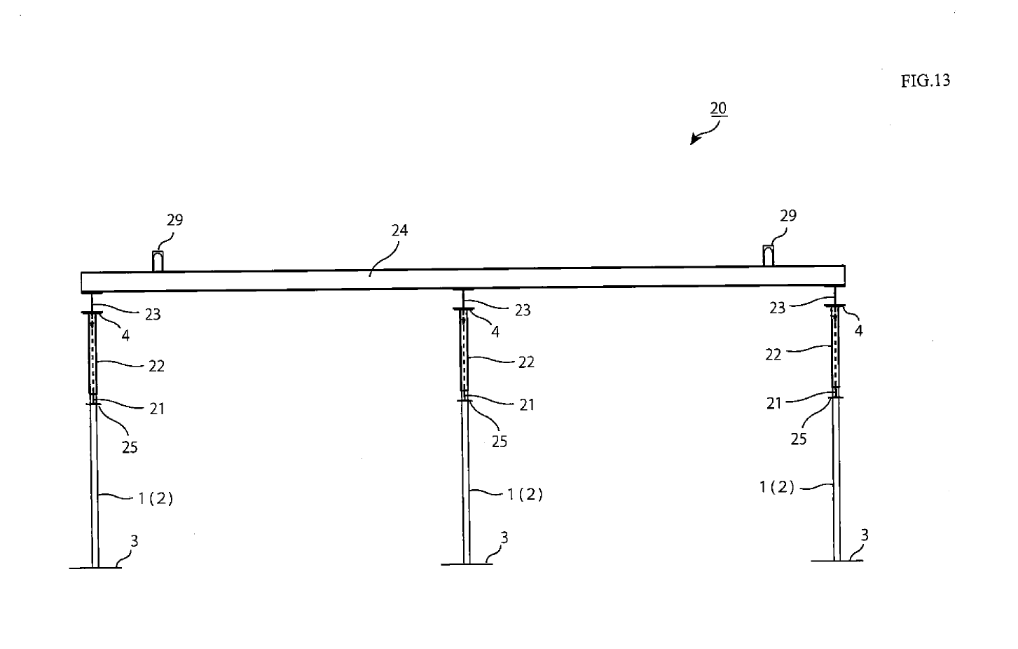

FIG. 13 is a front view showing the piles 1 mounted to the structure 20, and FIG. 14 is a side view of the same. Furthermore, when mounting piles 1 on the structure 20, as necessary, whether the plurality of piles 1 are in the prescribed positional relationships is confirmed as needed, and based on the result, fine adjustments of the positions at which piles 1 are mounted may be made.

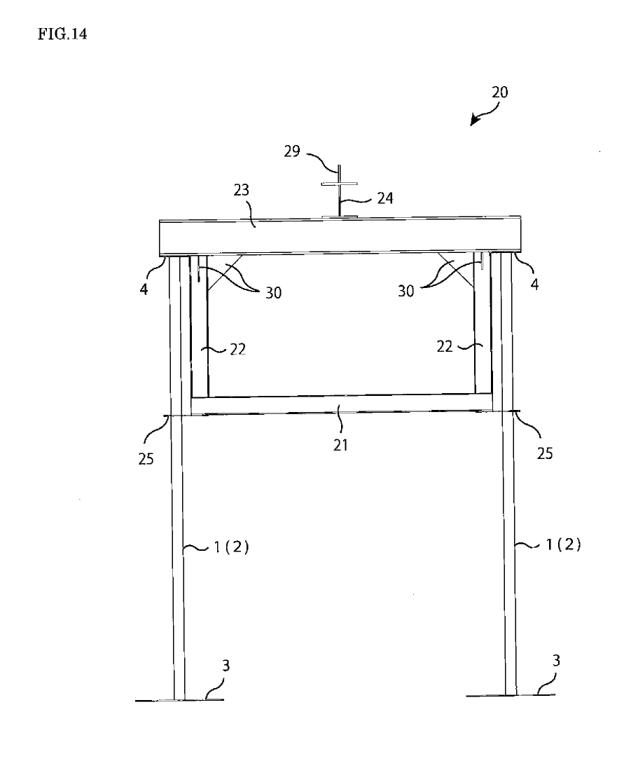

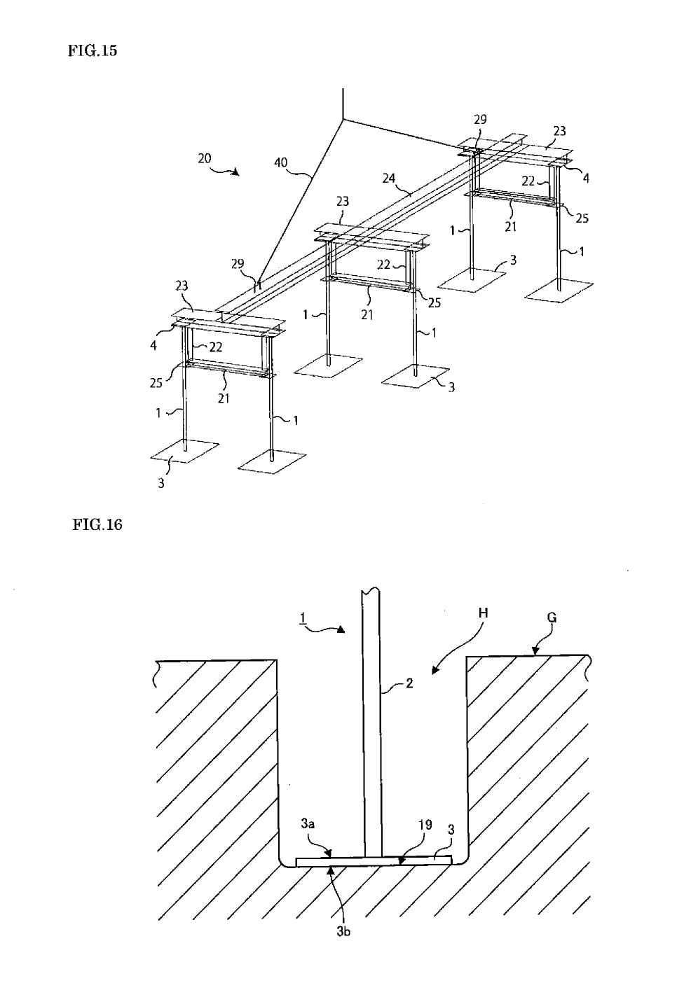

Next, as shown in FIG. 15, a wire 40 is attached to two metal hangers 29 of the vertical beam 24, and by hoisting the wire 40 by a crane, a plurality of piles 1 are hoisted integrally with the structure 20 while the aforementioned support condition is maintained. Next, by moving and turning a crane, the hoisted structure 20 and the plurality of piles 1 are transported to the installation site of the solar panel mounting stand 10. At the installation site, as shown in FIG. 12, planned installation ground surfaces 19 formed at the scheduled installation sites of the piles 1 are aligned with the positions of the corresponding piles 1, and the piles 1 are lowered together with the structure 20 by the crane; and then, as shown in FIG. 16, the lower end (the lower surface 3b of the projecting portion 3) of each pile 1 comes in contact with the corresponding planned installation ground surface 19.

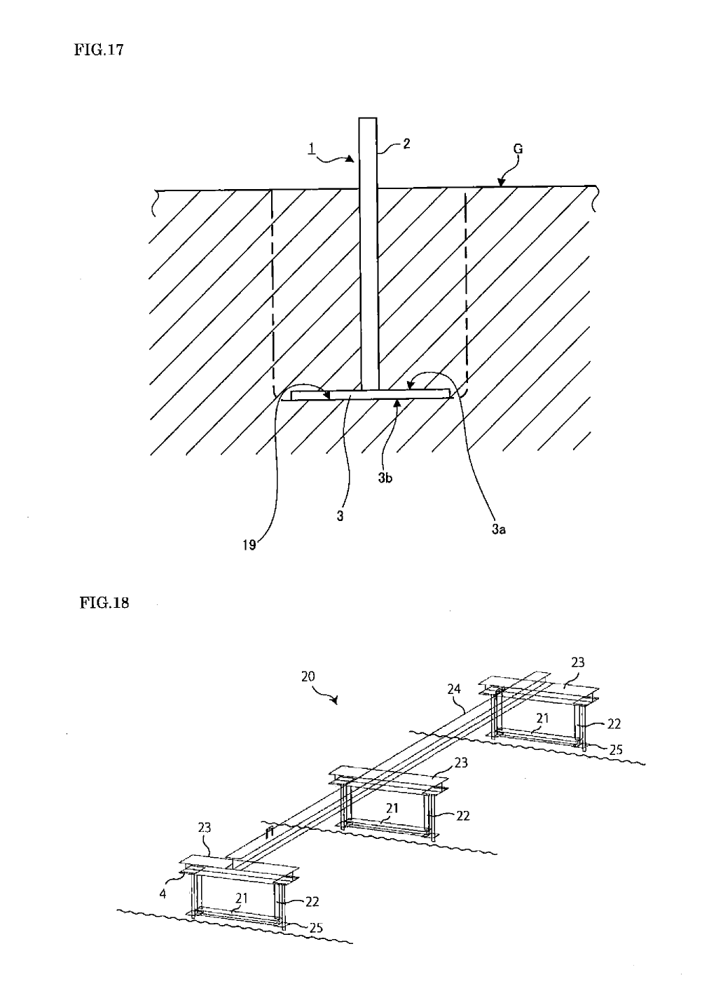

Next, as shown in FIG. 17 and FIG. 18, locations at which respective piles 1 were installed (in hole H in this embodiment) are refilled with the soil. Thus, the projecting portion 3 of the pile 1 is covered with soil and the lower end portion of the pile 1 is buried in the soil. At this time, the refilling soil is compacted as necessary. The soil refilling work should be conducted while the plurality of piles 1 are supported by the structure 20. This is because relative positional relationships of the plurality of piles 1 can be maintained even if a small amount of force is imposed on the piles 1 during a refilling process of the soil.

Thus, a plurality of piles 1 are installed at the installation site of the solar panel mounting stand 10.

Moreover, the soil that has been dug out to form the planned installation ground surfaces 19 can be used for the soil for refilling use. However, the soil used for refilling is not required to be the same soil that has been dug out.

Next, the structure 20 is removed from the plurality of piles 1. Specifically, the bolts and nuts that fasten the coupling portions 4 of respective piles 1 to the upper-tier transverse beams 23 are removed. Furthermore, braces 28 are removed from respective connecting fittings 25. Next, the entire structure 20 is horizontally moved to the opposite side of the opening of the notched portion 26 of the connecting fitting 25. Thus, the structure 20 is separated from the respective piles 1. A crane is used to move the structure 20. Thereafter, the structure 20 is hoisted by a crane and transported to a location distant from the installation site of the solar panel mounting stand 10. As a result, at the installation site of the solar panel mounting stand 10, as shown in FIG. 19, a plurality of (six in this embodiment) piles 1 are installed vertically (perpendicularly) upright. At this time, if the lengths of all piles 1 are the same, coupling portions 4 of respective piles 1 are disposed on the same virtual plane. Thus, the installed piles 1 serve as supporting legs 11 of the solar panel mounting stand 10.

Next, using a plurality of piles 1, members that constitute a framework of the solar panel mounting stand 10 are assembled. Member mounting work is conducted as described below.

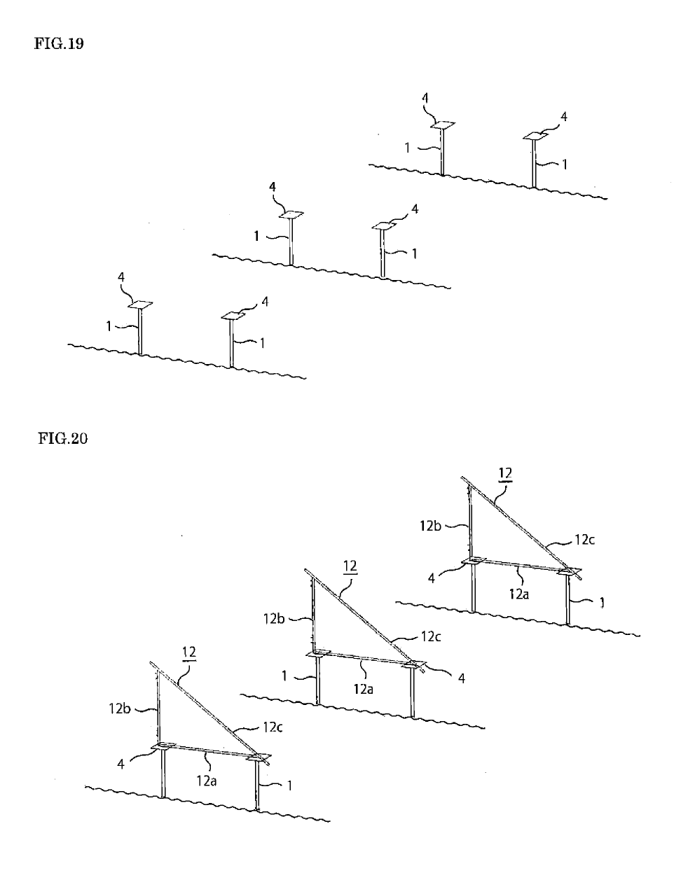

First, as shown in FIG. 20, panel supporting racks 12 are mounted on the piles 1. At this time, one panel supporting rack 12 is mounted on two piles 1 that are adjacent to each other in the lateral direction of the solar panel mounting stand 10. Since two mounting plates 18 are mounted on the lower surface of the steel member 12a of the panel supporting rack 12, the panel supporting rack 12 is placed on two piles 1 so that respective mounting plates 18 are placed on the coupling portions 4 of the respective piles 1. At that time, holes of the coupling portion 4 and those of the mounting plate 18 are aligned, and a bolt is inserted into each aligned hole and fastened by nuts. Thus, one panel supporting rack 12 is fixed to two piles 1. This mounting work is conducted for three panel supporting racks 12.

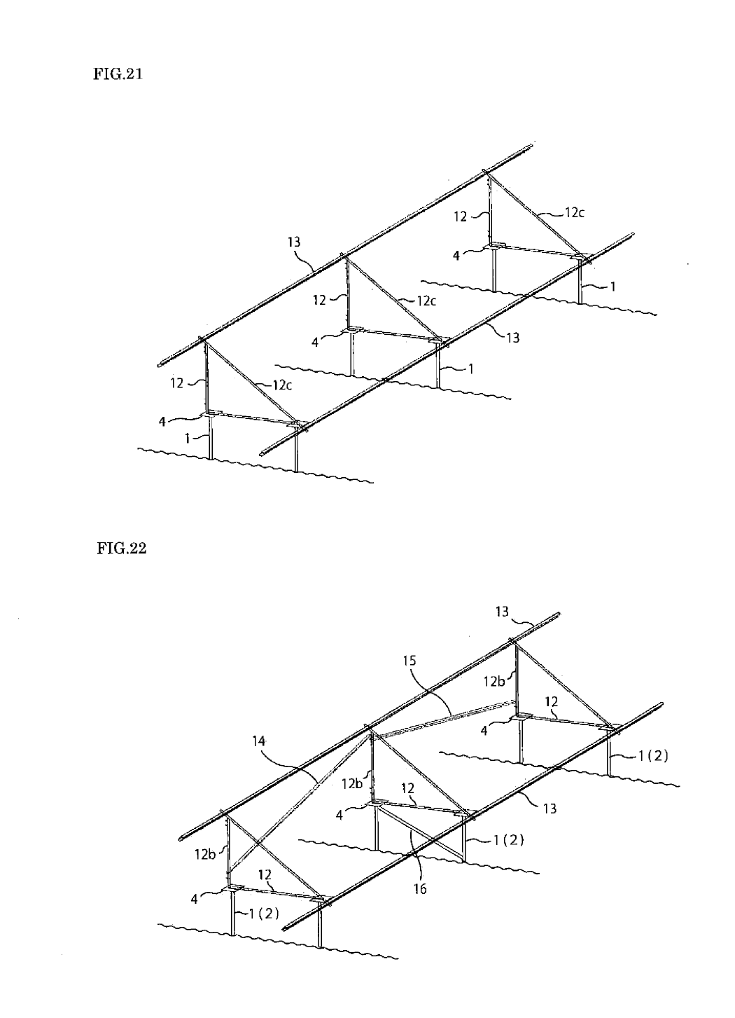

Next, as shown in FIG. 21, beam members 13 are installed on the panel supporting racks 12. The beam members 13 are mounted on three panel supporting racks 12 disposed in the longitudinal direction of the solar panel mounting stand 10 using bolts and nuts, for example. Holes used for mounting are provided beforehand in the panel supporting racks 12 and the beam members 13. Each beam member 13 is mounted on the upper side and the lower side of the steel member 12c constituting the oblique side of the panel supporting rack 12.

Next, as shown in FIG. 22, brace members 14, 15, and 16 are mounted. In this process, two brace members 14 and 15 are obliquely mounted from the panel supporting rack 12, disposed at the center in the longitudinal direction of the solar panel mounting stand 10, toward the panel supporting racks 12 disposed on both sides of the central panel supporting rack 12 so that a mountain shape is formed. Furthermore, the brace member 16 is mounted such that it connects two piles 1 (pile bodies 2) disposed at the center in the longitudinal direction of the solar panel mounting stand 10. The brace member 16 is mounted such that it is inclined in the same direction as the direction of the steel member 12c constituting the oblique side of the panel supporting rack 12. Brace members 14, 15, and 16 are mounted by using bolts and nuts, for example. Holes used for mounting work are provided beforehand in the panel supporting racks 12 and the piles 1.

Moreover, brace members 14 and 15 may be mounted at any time after the panel supporting racks 12 have been mounted. Similarly, the brace member 16 may be mounted at any time after piles 1 have been installed.

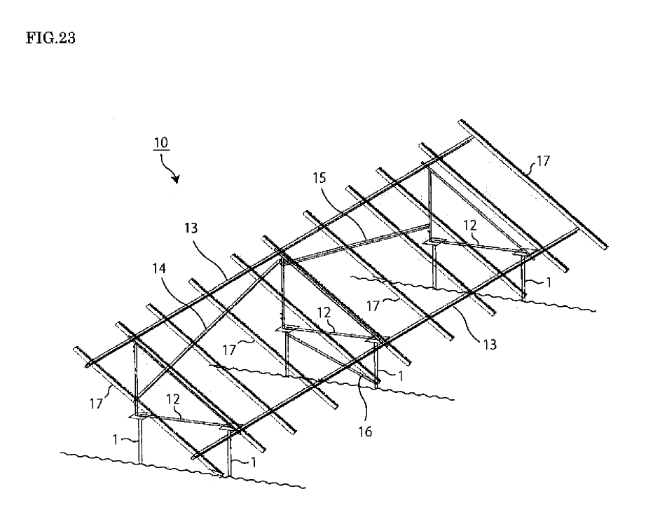

Next, as shown in FIG. 23, panel receiving members 17 are mounted on the beam members 13. The panel receiving members 17 are mounted such that they extend across two beam members 13. Furthermore, a plurality of panel receiving members 17 are mounted in the longitudinal direction of the solar panel mounting stand 10 at predetermined intervals. The panel receiving members 17 are mounted by using bolts and nuts, for example. Holes used for mounting work are provided beforehand in the beam members 13 and the panel receiving members 17.

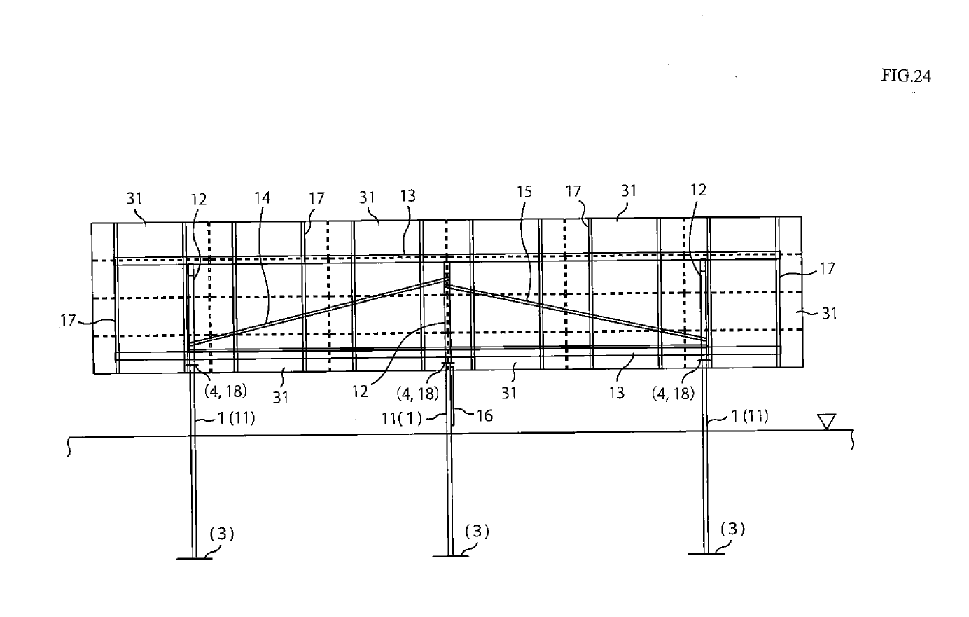

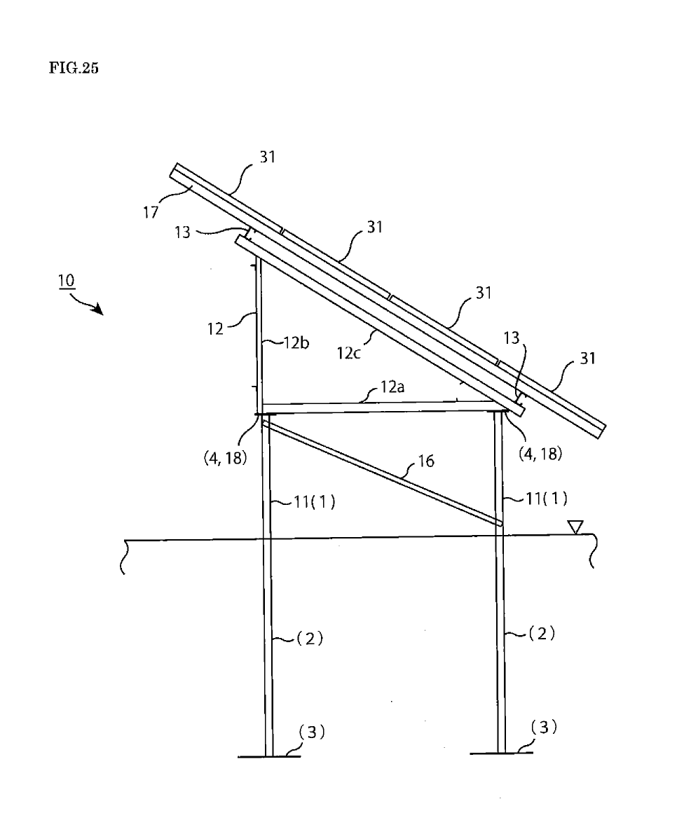

Thus, installation of the solar panel mounting stand 10 is completed. Thereafter, as shown in the front view of FIG. 24 and in the side view of FIG. 25, a plurality of solar panels 31 are mounted on the solar panel mounting stand 10. In FIG. 24, solar panels 31 appear to be transparent so that positional relationships among all the constituent members of the structure 20 and the solar panels 31 are clarified.

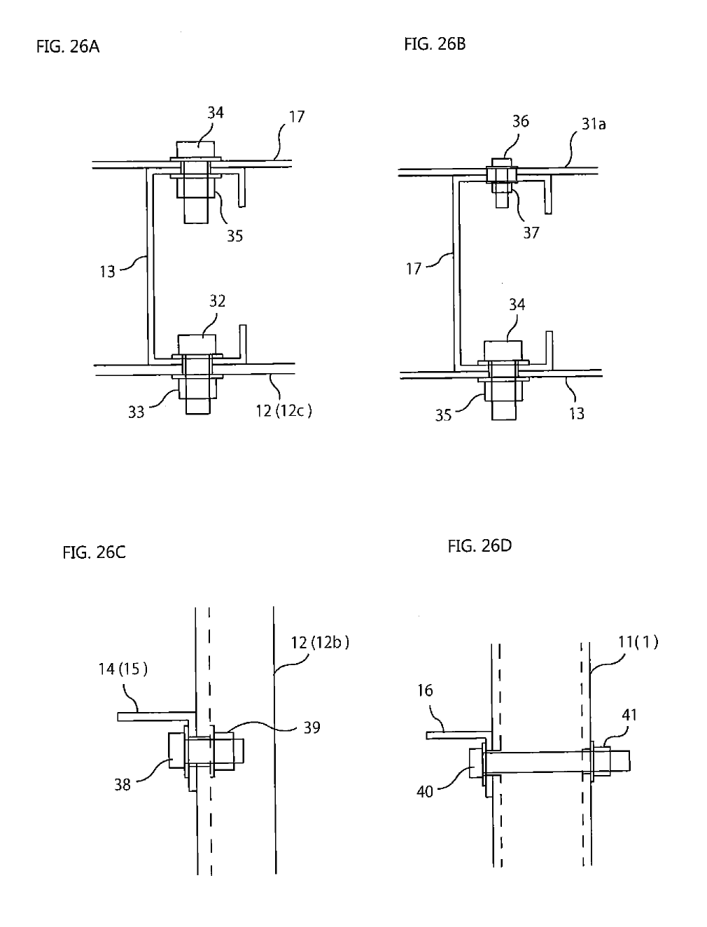

FIG. 26 shows specific structural examples where respective members are fastened by bolts and nuts. In FIG. 26(A) and FIG. 26(B), the panel supporting rack 12 and the beam member 13 are fastened by a bolt 32 and a nut 33, and the beam member 13 and the panel receiving member 17 are fastened by a bolt 34 and a nut 35. And, the frame member 31 a of the solar panel is fastened to the panel receiving member 17 by a bolt 36 and a nut 37. Meanwhile, in FIG. 26(C), the panel supporting rack 12 and the brace member 14 (15) are fastened by a bolt 38 and a nut 39; and in FIG. 26(D), the pile 1 that serves as a supporting leg 11 and the brace member 16 are fastened by a bolt 40 and a nut 41. Moreover, the way of fixing members is not limited to the fixing structure of using bolts and nuts, and for example, a fixing structure using fixing brackets not shown, or a fixing means such as welding can be adopted. However, when taking into account the construction cost and material cost, it is preferred that the fixing structure using bolts and nuts be adopted.

<5. Effects of the Embodiment of the Present Invention>

In a solar panel mounting stand 10 according to an embodiment of the present invention, solar panels are designed to be mounted at an inclined angle to the horizontal plane; however, it is possible to ensure the necessary rigidity and also reduce the number of constituent members necessary for assembly. Consequently, it is possible to reduce the cost for installing the solar panel mounting stand. Hereinafter, a detailed description will be given.

According to a structure of this embodiment, an integrally-structured right triangle panel supporting rack 12 is used, and solar panels 31 are obliquely mounted using the inclination of the steel member 12b constituting the oblique side of the panel supporting rack 12. With this structure, the integrally-structured panel supporting rack 12 has superior rigidity. Therefore, it is possible for the panel supporting rack 12 to securely support beam members 13 and panel receiving members 17 mounted on the panel supporting rack 12, and solar panels 31 further mounted on top of those members. In this case, respective steel members 12c of three panel supporting racks 12 are mutually connected by two beam members 13, and respective steel members 12b of three panel supporting racks 12 are mutually connected by two brace members 14 and 15; thus, this combination of a small number of members can provide superior rigidity for the entire solar panel mounting stand 10. Consequently, it is possible to ensure the rigidity required for the solar panel mounting stand 10 and also reduce the installation cost.

Furthermore, in this case, two brace members 14 and 15 function to inhibit the solar panel mounting stand 10 from rocking in the longitudinal direction as well as inhibiting supporting legs 11 from being pulled off. Specifically, if a force is applied to rock the solar panel mounting stand 10 in one direction in the longitudinal direction, the brace member 14 provides resistance against the force, thereby inhibiting the entire solar panel mounting stand 10 from rocking. At this time, a relatively heavy load is imposed, via the brace member 15, on the supporting leg 11 disposed on one side in the longitudinal direction of the solar panel mounting stand 10. This load acts on the supporting leg 11 downward.

Furthermore, if a force is applied to rock the solar panel mounting stand 10 in the other direction in the longitudinal direction, the brace member 15 provides resistance against the force, thereby inhibiting the entire solar panel mounting stand 10 from rocking. At this time, a relatively heavy load is imposed, via the brace member 15, on the supporting leg 11 disposed on the other side in the longitudinal direction of the solar panel mounting stand 10. This load acts on the other supporting leg 11 downward.

Based on the above, respective supporting legs 11 disposed on one side and on the other side in the longitudinal direction of the solar panel mounting stand 10 bear the forces that press the legs downward to the ground as to the rocking in the longitudinal direction of the solar panel mounting stand 10. Therefore, two brace members 14 and 15 function to inhibit the solar panel mounting stand 10 from rocking in the longitudinal direction as well as inhibiting supporting legs 11 from being pulled off As a result, it is possible to simultaneously inhibit the rocking of the solar panel mounting stand 10 and inhibit the pull-off of the supporting legs 11.

Furthermore, in this embodiment, two supporting legs 11 that are adjacent to each other in the lateral direction of the solar panel mounting stand 10 are mutually connected by a brace member 16, and the brace member 16 is disposed such that it is inclined in the same direction as the steel member 12c of the panel supporting rack 12. Therefore, it is possible to inhibit the solar panel mounting stand 10 from rocking in the lateral direction by the brace member 16. Specifically, in the structure that solar panels 31 are obliquely mounted, a relatively heavy load is imposed on the supporting leg 11 disposed on the lower-level side of the solar panels 31. Therefore, by mounting the brace member 16 at an inclined angle in the same direction as the solar panels 31, it is possible to effectively inhibit the solar panel mounting stand 10 from rocking by using the brace member 16.

Furthermore, in this embodiment, the pile 1 having the projecting portion 3 at the lower end of the pile body 2, is used as a supporting leg 11 of the solar panel mounting stand 10. Therefore, the presence of the projecting portion 3 inhibits the supporting leg 11 from being pulled-off as well as inhibiting the sinking of the supporting leg 11 when a strong pressing force is imposed on the supporting leg 11 via respective brace members 14, 15, and 16. As a result, it is possible to simultaneously increase the rigidity of the solar panel mounting stand 10 and inhibit the pull-off and sinking of the supporting legs 11.

<6. Modified Example, etc.>

Moreover, the technical scope of the present invention is not limited to the aforementioned embodiment, and includes variety of modifications and alterations within a scope capable of deriving specific effects obtained by constituting features of the invention and a combination of them.

For example, in the above embodiment, a cross-sectional shape of the pile body 2 is circular; however, the present invention is not limited thereto, and the cross-sectional shape of the pile body 2 may be a prismatic column such as a quadrangular prism.

Furthermore, the planar shape of the projecting portion 3 is not limited to a square or other quadrangles, and can be of any shape as long as it receives the load of the refilling soil on the surface thereof; for example, it can be a polygon, circle, oval, flower-petal shape, or cross-like figure. Furthermore, in addition to providing the projecting portion 3 at the lower end of the pile body 2, two or three projecting portions may be disposed at the lower end portion of the pile body 2, which is eventually buried in the soil, at certain intervals in the longitudinal direction of the pile body 2.

Furthermore, it is preferred that the projecting portion 3 be formed into a flat plate-like shape so as to be a simple structure and efficiently bear the load of the soil; however, the shape is not limited to the flat plate-like shape. For example, although not shown, a part of or the entire outer circumference edge of the projecting portion 3 may be bent upward. Furthermore, when the projecting portion 3 is formed into a plate-like shape, instead of disposing the projecting portion 3 at a right angle with regard to the central axis of the pile body 2, the projecting portion 3 may be disposed slightly inclined (preferably, an inclined angle of more than 0 degrees, and equivalent to or less than 30 degrees). However, since piles used in the present invention are not driven or screwed into the ground, spiral-shaped piles are excluded.

Furthermore, at the installation site of the solar panel mounting stand 10, three supporting legs 11 are disposed in a row in the longitudinal direction of the solar panel mounting stand 10, and two supporting legs 11 are disposed in a row in the lateral direction of the same, and six supporting legs 11 in total are installed as a set. However, another supporting leg 11 may additionally be installed as needed between the supporting leg 11 disposed at the center and the supporting leg 11 disposed at one end (or the other end). Specifically, if a space between the supporting leg 11 disposed at the center in the longitudinal direction of the solar panel mounting stand 10 and the supporting leg 11 disposed at one end (or the other end) is very wide, the supporting leg 11 and the panel supporting rack 12 may be added therebetween as needed.

Furthermore, because panel receiving members 17 are made of lip groove steel, by changing the dimensions (mainly length) of the actually-used lip groove steel, hole positions, the number of members, etc., it is possible to mount different manufacturers' solar panels or change the number of solar panels made by the same manufacturer.

Furthermore, constituent material of the solar panel mounting stand is not limited to steel, and it can be any material as long as it satisfies the mechanical strength, durability, antiweatherability, etc., required by the solar panel mounting stand; for example, other metal (including alloy) such as stainless-steel, aluminum, etc., and plastic such as reinforced plastic may be used.

1. A solar panel mounting stand configured to mount a solar panel thereon in an inclination state inclined obliquely to a horizontal plane, comprising:
a plurality of supporting legs installed at an installation site, with six supporting legs in total as one set including three supporting legs arranged in a row in a first direction and two supporting legs arranged in a row in a second direction perpendicular to the first direction at the installation site of the solar panel mounting stand;
three panel supporting racks, having an integral structure in which three members are combined to form a right triangle, and mounted on adjacent two supporting legs in the second direction;
a beam member configured to mutually connect members constituting an oblique side of the three panel supporting racks arranged in a row in the first direction;
a first brace member configured to connect a member constituting a vertical side of the panel supporting rack mounted on a central supporting leg of three supporting legs adjacent to each other in the first direction, and a member constituting the vertical side of the panel supporting rack mounted on a supporting leg of the three supporting legs at one end side; and
a second brace member configured to connect a member constituting the vertical side of the panel supporting rack mounted on the central supporting leg of the three supporting legs adjacent to each other in the first direction, and a member constituting the vertical side of the panel supporting rack mounted on a supporting leg of the three supporting legs at the other end side;
wherein the first brace member and the second brace member are disposed in a form a mountain shape when said solar panel mounting stand is viewed from a front direction.

2. The solar panel mounting stand according to claim 1, further comprising
a third brace member configured to mutually connect two supporting legs adjacent to each other in the second direction and disposed in an inclination state inclined in the same direction as the direction of the member constituting the oblique side of the panel supporting rack.

3. The solar panel mounting stand according to claim 1, wherein a projecting portion is provided on a lower end of the supporting leg, which is configured to inhibit a pull-off of the supporting leg under a load of the soil when a lower end side of the supporting leg is buried in the soil.

4. The solar panel mounting stand according to claim 2, wherein a projecting portion is provided on a lower end of the supporting leg, which is configured to inhibit a pull-off of the supporting leg under a load of the soil when a lower end side of the supporting leg is buried in the soil.
